(19) United States
(12) Patent Application Publication
(10) Pub. No.: US 2026/0190733 A1
(43) Pub. Date: Jul. 2, 2026

(54) Display Device

(71) Applicant: LG Display Co., Ltd., Seoul (KR)

(72) Inventors: Seungryong Joung, Seoul (KR); Yeonsuk Kang, Seoul (KR)

(21) Appl. No.: 19/366,046

(22) Filed: Oct. 22, 2025

(30) Foreign Application Priority Data
Dec. 26, 2024 (KR) 10-2024-0197286

(51) Int. Cl. H10K 59/35; H10K 59/00; H10K 59/12; H10K 101/40

(52) U.S. Cl. CPC H10K 59/353; H10K 59/1201; H10K 59/771; H10K 2101/40

(57) ABSTRACT

A display device includes a substrate; and first to third sub-pixels disposed on the substrate, wherein the first sub-pixel includes: a first anode electrode disposed on the substrate; and a hole transport layer, a red light-emitting material layer, a green light-emitting material layer, a blue light-emitting material layer, and an electron transport layer sequentially stacked on the first anode electrode, wherein the second sub-pixel includes: a second anode electrode disposed on the substrate; and a hole transport layer, a green light-emitting material layer, a blue light-emitting material layer, and an electron transport layer sequentially stacked on the second anode electrode, wherein the third sub-pixel includes: a third anode electrode disposed on the substrate; and a hole transport layer, a blue light-emitting material layer, and an electron transport layer sequentially stacked on the third anode electrode.

### CROSS REFERENCE TO RELATED APPLICATION

The present application claims priority under 35 U.S.C. § 119(a) to the Republic of Korea Patent Application No. 10-2024-0197286, filed on Dec. 26, 2024, the entire contents of which are hereby expressly incorporated by reference into the present application.

### TECHNICAL FIELD

The present disclosure relates to a display device.

### BACKGROUND

An organic light-emitting display device of a self-emission type has a larger viewing angle, and a higher contrast ratio compared to a liquid crystal display device, and does not require a separate backlight, thereby enabling a display device of a lightweight and thin type, and is advantageous in terms of power consumption. In addition, the organic light-emitting display device can operate at a low direct current voltage, has a fast response speed, and particularly, has a low manufacturing cost.

Recently, a head mounted display device for implementing Virtual Reality (VR) or Augmented Reality (AR) has been developed.

### SUMMARY

In order to improve the stereoscopic effect, realism, and immersion of an image implemented in the head-mounted display device, the head-mounted display device requires a display panel for displaying a high-resolution image.

In order to implement a high-resolution display panel, an organic light-emitting display panel having a new structure in which an organic light-emitting element is formed on a silicon substrate has been developed.

Conventionally, a fine metal mask (FMM) has been used to deposit different organic light-emitting materials emitting color of different colors in red sub-pixels, green sub-pixels, and blue sub-pixels. However, the use of the FMM has limitations in increasing a resolution of the organic light-emitting display panel.

Thus, an alternative thereto has been proposed in which an organic light-emitting element emitting white light is commonly disposed in red, green, and blue sub-pixels in order to implement a high-resolution organic light-emitting display panel. The organic light-emitting device emitting white light has a tandem structure including two or more light-emitting stacks emitting light of different colors. There is a problem in that power consumption of the high-resolution display panel including the organic light-emitting element having the tandem structure increases.

A technical purpose of the present disclosure is to provide a display device capable of providing a high-resolution image to a user and reducing power consumption.

A technical purpose of the present disclosure is to provide a method for manufacturing a high-resolution display device having a red light-emitting element, a green light-emitting element, and a blue light-emitting element without using a fine metal mask (FMM).

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

One aspect of the present disclosure provides a display device comprising: a substrate; and a first sub-pixel, a second sub-pixel, and a third sub-pixel disposed on the substrate, wherein the first sub-pixel includes: a first anode electrode disposed on the substrate; and a hole transport layer, a red light-emitting material layer, a green light-emitting material layer, a blue light-emitting material layer, and an electron transport layer sequentially stacked on the first anode electrode, wherein the second sub-pixel includes: a second anode electrode disposed on the substrate; and a hole transport layer, a green light-emitting material layer, a blue light-emitting material layer, and an electron transport layer sequentially stacked on the second anode electrode, wherein the third sub-pixel includes: a third anode electrode disposed on the substrate; and a hole transport layer, a blue light-emitting material layer, and an electron transport layer sequentially stacked on the third anode electrode.

Another aspect of the present disclosure provides a method for manufacturing a display device including a first sub-pixel, a second sub-pixel, and a third sub-pixel, the method comprising: providing a backplane substrate including a first anode electrode disposed in the first sub-pixel, a second anode electrode disposed in the second sub-pixel, and a third anode electrode disposed in the third sub-pixel; depositing a hole transport layer on the first to third anode electrodes in the first to third sub-pixels; depositing a red light-emitting material layer on the hole transport layer in the first to third sub-pixels; removing the red light-emitting material layer from each of the second and third sub-pixels; depositing a green light-emitting material layer in the first to third sub-pixels; removing the green light-emitting material layer from the third sub-pixel; and depositing a blue light-emitting material layer in the first to third sub-pixels.

According to embodiments of the present disclosure, realized is a display device which has a red light-emitting element, a green light-emitting element, a blue light-emitting element, in which a red light-emitting material layer, a green light-emitting material layer, and a blue light-emitting material layer are stacked in a first sub-pixel, a green light-emitting material layer, and a blue light-emitting material layer are stacked in a second sub-pixel, a blue light-emitting material layer is disposed in a third sub-pixel, and energy is allowed to transfer from the blue light-emitting material layer to the green light-emitting material layer, and from the green light-emitting material layer to the red light-emitting material layer, thereby providing a high resolution image and reducing power consumption.

According to embodiments of the present disclosure, a high-resolution display device having a red light-emitting element, a green light-emitting element, and a blue light-emitting element may be manufactured without using a fine metal mask (FMM) by depositing a red light-emitting material layer in the first to third sub-pixels and then removing the red light-emitting material layer from the second and third sub-pixels, and depositing a green light-emitting material layer in the first to third sub-pixels and then removing the green light-emitting material layer from the third sub-pixel, and then depositing a blue light-emitting material layer in the first to third sub-pixels.

The effects of the present disclosure are not limited to the above-mentioned effects, and other effects not mentioned may be clearly understood by those skilled in the art from the following descriptions.

In addition to the above-described effects, the specific effects of the present disclosure will be described together while describing specific matters for implementing the embodiments of the present disclosure below.

### BRIEF DESCRIPTION OF THE DRAWINGS

FIG. 1 is a plan view schematically illustrating a display device according to an embodiment of the present disclosure.

FIG. 2 is a cross-sectional view taken along a line II-II of FIG. 1.

FIG. 3 schematically illustrates a stack structure of each of sub-pixels of a display device according to an embodiment of the present disclosure.

FIGS. 4A to 4G schematically illustrate a method for manufacturing a display device according to an embodiment of the present disclosure.

FIGS. 5A to 5C illustrate energy levels of sub-pixels of a display device according to an embodiment of the present disclosure.

FIGS. 6A to 6C illustrate a recombination profile of each of sub-pixels of a display device according to an embodiment of the present disclosure.

FIG. 7 schematically illustrates a stack structure of each of sub-pixels of a display device according to an embodiment of the present disclosure.

FIG. 8 schematically illustrates a stack structure of each of sub-pixels of a display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to, or coupled to the other element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present.

Further, as used herein, when a layer, film, area, plate, or the like is disposed “on” or “on top” of another layer, film, area, plate, or the like, the former may directly contact the latter or still another layer, film, area, plate, or the like may be disposed between the former and the latter. As used herein, when a layer, film, area, plate, or the like is directly disposed “on” or “on top” of another layer, film, area, plate, or the like, the former directly contacts the latter and still another layer, film, area, plate, or the like is not disposed between the former and the latter. Further, as used herein, when a layer, film, area, plate, or the like is disposed “beneath” or “under” another layer, film, area, plate, or the like, the former may directly contact the latter or still another layer, film, area, plate, or the like may be disposed between the former and the latter. As used herein, when a layer, film, area, plate, or the like is directly disposed “beneath” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or period. Thus, a first element, component, area, layer or section as described under could be termed a second element, component, area, layer or period, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs.

Further, the term ‘or’ means ‘inclusive or’ rather than ‘exclusive or'. That is, unless otherwise stated or clear from the context, the expression that 'x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed descriptions.

In description of flow of a signal, for example, when a signal is delivered from a node A to a node B, this may include a case where the signal is transferred from the node A to the node B via another node unless a phrase ‘immediately transferred’or ‘directly transferred’is used.

Throughout the present disclosure, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components means not only a first, second, or third component, but also all combinations of two or more of the first, second, and third components.

Hereinafter, embodiments of the present disclosure will be described using the attached drawings. A scale of each of components as shown in the drawings is different from an actual scale thereof for convenience of illustration, and therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to an embodiment of the present disclosure will be described with reference to the drawings.

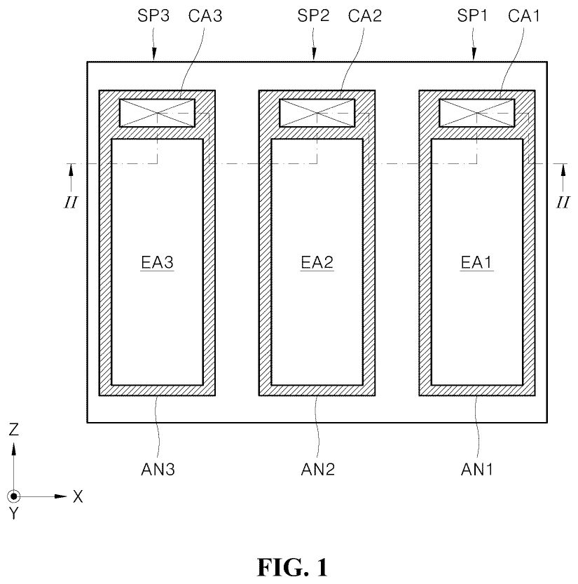

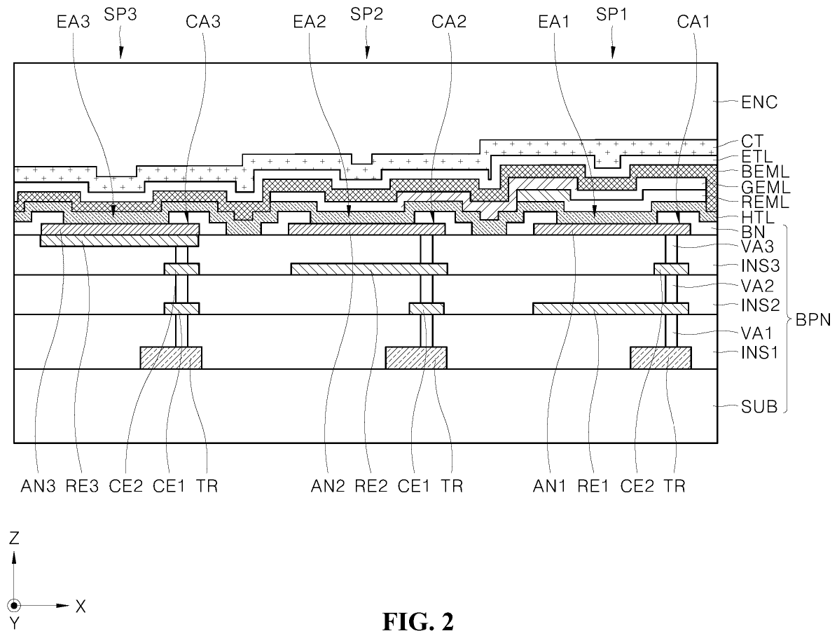

FIG. 1 is a plan view schematically illustrating a display device according to an embodiment of the present disclosure. FIG. 2 is a cross-sectional view taken along a line II-II of FIG. 1.

Referring to FIGS. 1 and 2, the display device according to an embodiment of the present disclosure may include a substrate SUB, a transistor TR, first to third insulating layers INS1, INS2, and INS3, first to third reflective electrodes RE1, RE2, and RE3, first and second contact electrodes CE1 and CE2, first and second contact vias VA1 and VA2, first to third anode electrodes AN1, AN2, and AN3, a bank BN, a red light-emitting layer REML, a green light-emitting layer GEML, a blue light-emitting layer BEML, a cathode electrode CT, and an encapsulation layer ENC (FIG. 2). The substrate SUB, the transistor TR, the first to third insulating layers INS1, INS2, and INS3, the first to third reflective electrodes RE1, RE2, and RE3, the first and second contact electrodes CE1 and CE2, the first and second contact vias VA1 and VA2, the first to third anode electrodes AN1, AN2, and AN3, and the bank BN may constitute a backplane substrate BPN.

The display device according to an embodiment of the present disclosure may be implemented in a so-called top emission manner in which light emitted from a light-emitting layer is emitted in an upward direction so as to be away from a substrate.

The substrate SUB may be made of a semiconductor material such as silicon (Si). The substrate SUB may be a semiconductor substrate.

For example, a first sub-pixel SP1, a second sub-pixel SP2, and a third sub-pixel SP3, which are arranged in the X direction, are provided on the substrate SUB. The first sub-pixel SP1 may emit red light, the second sub-pixel SP2 may emit green light, and the third sub-pixel SP3 may emit blue light. The arrangement order and arrangement direction of the sub-pixels SP1, SP2, and SP3 may be variously changed.

A driving circuit including various circuit lines, transistors TR, and a capacitor is provided on the substrate SUB and in each of the sub-pixels SP1, SP2, and SP3. The circuit lines may include a gate line, a data line, a power line, and a reference line, and the transistors TR may include a switching transistor, a driving transistor, and a sensing transistor. For example, the transistors TR may be formed on the substrate SUB using a CMOS process.

The first insulating layer INS1 may be disposed on the substrate SUB. The first insulating layer INS1 may be made of an inorganic insulating material or an organic insulating material. The first insulating layer INS1 may cover the transistors TR, various circuit lines, a capacitor, etc., which are disposed on the substrate SUB.

The first reflective electrode RE1 and the first contact electrodes CE1 may be disposed on the first insulating layer INS1. The first reflective electrode RE1 may be disposed in the first sub-pixel SP1, and the first contact electrodes CE1 may be disposed in the second sub-pixel SP2 and the third sub-pixel SP3, respectively.

The first contact vias VA1 may be disposed to extend through the first insulating layer INS1. The first contact via VA1 may be disposed in, for example, each of the first to third contact areas CA1, CA2, and CA3.

In the first sub-pixel SP1, the first reflective electrode RE1 or the first contact electrode CE1 may be connected to the transistor TR via the first contact via VA1 extending through the first insulating layer INS1. In the first contact area CA1 of the first sub-pixel SP1, the first reflective electrode RE1 may be connected to the transistor TR via the first contact via VA1 extending through the first insulating layer INS1. In the second contact area CA2 of the second sub-pixel S2P the first contact electrode CE1 may be connected to the transistor TR via the first contact via VA1 extending through the first insulating layer INS1. In the third contact area CA3 of the third sub-pixel SP3, the first contact electrode CE1 may be connected to the transistor TR via the first contact via VA1 extending through the first insulating layer INS1.

In an embodiment, the first reflective electrode RE1 and the first contact via VA1 may be integrally formed with each other or monolithic in the first sub-pixel SP1. In the second sub-pixel SP2, the first contact electrode CE1 and the first contact via VA1 may be integrally formed with each other or monolithic. In the third sub-pixel SP3, the first contact electrode CE1 and the first contact via VA1 may be integrally formed with each other or monolithic.

The first reflective electrode RE1 and the first contact electrode CE1 may be made of a metal material having high reflectivity, such as silver (Ag), a silver alloy, aluminum (Al), or an aluminum alloy. The first contact via VA1 may include a metal material.

The second insulating layer INS2 may be disposed on the first insulating layer INS1, and the second insulating layer INS2 may cover the first reflective electrode RE1 and the first contact electrodes CE1.

The second insulating layer INS2 may be made of an inorganic insulating material or an organic insulating material.

The second reflective electrode RE2 and the second contact electrodes CE2 may be disposed on the second insulating layer INS2. The second reflective electrode RE2 may be disposed in the second sub-pixel SP2, and the second contact electrodes CE2 may be disposed in the first sub-pixel SP1 and the third sub-pixel SP3, respectively.

The second contact vias VA2 may be disposed to extend through the second insulating layer INS2. Each of the second contact vias VA2 may be disposed, for example, in each of the first to third contact areas CA1, CA2, and CA3.

In the first contact area CA1 of the first sub-pixel SP1. the second contact electrode CE2 may be connected to the first reflective electrode RE1 via the second contact via VA2 extending through the second insulating layer INS2. In the second contact area CA2 of the second sub-pixel SP2, the second reflective electrode RE2 may be connected to the first contact electrode CE1 via the second contact via VA2 extending through the second insulating layer INS2. In the third contact area CA3 of the third sub-pixel SP3, the second contact electrode CE2 may be connected to the first contact electrode CE1 via the second contact via VA2 extending through the second insulating layer INS2.

The second reflective electrode RE2 and the second contact electrodes CE2 may be made of a metal material having high reflectance, such as silver (Ag), a silver alloy, aluminum (Al), or an aluminum alloy. The second contact via VA2 may include a metal material.

In an embodiment, the second contact electrode CE2 and the second contact via VA2 may be integrally formed with each other or monolithic in the first sub-pixel SP1. In the second sub-pixel SP2, the second reflective electrode RE2 and the second contact via VA2 may be integrally formed with each other or monolithic. In the third sub-pixel SP3, the second contact electrode CE2 and the second contact via VA2 may be integrally formed with each other or monolithic.

The third insulating layer INS3 may be disposed on the second insulating layer INS2, and the third insulating layer INS3 may cover the second reflective electrode RE2 and the second contact electrodes CE2.

The third insulating layer INS3 may be made of an inorganic insulating material or an organic insulating material.

The first anode electrode AN1, the second anode electrode AN2, the third reflective electrode RE3, and the third anode electrode AN3 may be disposed on the third insulating layer INS3. The first anode electrode AN1 may be disposed in the first sub-pixel SP1, the second anode electrode AN2 may be disposed in the second sub-pixel SP2, and the third reflective electrode RE3 and the third anode electrode AN3 may be disposed in the third sub-pixel SP3.

In the third sub-pixel SP3, the third reflective electrode RE3 and the third anode electrode AN3 may be in contact with each other.

The third contact vias VA3 may be disposed to extend through the third insulating layer INS3. In one example, each of the third contact vias VA3 may be disposed in each of the first to third contact areas CA1, CA2, and CA3.

In the first contact area CA1 of the first sub-pixel SP1, the first anode electrode AN1 may be connected to the second contact electrode CE2 via the third contact via VA3 extending through the third insulating layer INS3. In the second contact area CA2 of the second sub-pixel SP2, the second anode electrode AN2 may be connected to the second reflective electrode RE2 via the third contact via VA3 extending through the third insulating layer INS3. In the third contact area CA3 of the third sub-pixel SP3, the third reflective electrode RE3 may be connected to the second contact electrode CE2 via the third contact via VA3 extending through the third insulating layer INS3.

In an embodiment, instead of contacting the third reflective electrode RE3 and the third anode electrode AN3 with each other, an additional insulating layer may be further disposed on the third reflective electrode RE3, and the first to third anode electrodes AN1, AN2, and AN3 may be disposed on the insulating layer. In this case, the third reflective electrode RE3 and the third anode electrode AN3 may be connected to each other via an additional contact via.

The third reflective electrode RE3 may be made of a metal material having high reflectance, such as silver (Ag), a silver alloy, aluminum (Al), or an aluminum alloy. The third contact via VA3 may include a metal material. Each of the first to third anode electrodes AN1, AN2, and AN3 may be made of a transparent conductive material such as ITO and IZO capable of transmitting light therethrough.

Each of the first to third anode electrodes AN1, AN2, and AN3 may be electrically connected to a source terminal or a drain terminal of the driving transistor disposed on the substrate SUB.

The bank BN is disposed on the third insulating layer INS3 so as to cover an edge area of each of the first to third anode electrodes AN1, AN2, and AN3. A portion of an upper surface of the first anode electrode AN1 not covered with the bank BN so as to be exposed may be a first light emission area EA1. A portion of an upper surface of the second anode electrode AN2 not covered with the bank BN so as to be exposed may be a second light emission area EA2. A portion of an upper surface of the third anode electrode AN3 not covered with the bank BN so as to be exposed may be a third light emission area EA3.

The bank BN may be made of an inorganic insulating material. In an embodiment, the bank BN may be made of an organic insulating material.

Different light-emitting layers in different sub-pixels may be configured to emit light of different colors. The first sub-pixel SP1 may emit red light, the second sub-pixel SP2 may emit green light, and the third sub-pixel SP3 may emit blue light.

A hole transport layer HTL may be commonly disposed in the first sub-pixel SP1, the second sub-pixel SP2, and the third sub-pixel SP3. The hole transport layer HTL may be disposed on the first to third anode electrodes AN1, AN2, and AN3, and the bank BN.

The hole transport layer HTL may be an inorganic hole transport layer. The hole transport layer HTL may be made of an inorganic material. The inorganic material may include a Ni derivative, a Cu derivative, a carbon-based material, etc. The Ni derivative may include NiOₓ, nickel sulfide-carbon (NiSC), and Cu doped NiOₓ. The Cu derivative may include copper iodide (CuI), CuO, Cu₂O, CuOx, CuS, CuCrO₂, CuGaO₂, CuAlO₂, Cu₃SbS₄, CuFeO₂, CuSCN, Cu₂ZnSnS₄, CuBaSnS₄, and CuInSe₂. The carbon-based material may include carbon, graphene oxide, reduced graphene oxide, and carbon nanotubes. The hole transport layer HTL may include MoO₂, MoO₃, VOₓ, V₂Oₓ, WOₓ, MoS₂, Bi₂S₃, TeOₓ, Bi₂O₃, Sb₂O₃, CoOₓ, CrOₓ, MnS, or the like. In order to smoothly supply holes to the light-emitting material layers, the hole mobility of the hole transport layer HTL is preferably 1×10⁻³ cm²/V·sec or greater. The hole transport layer HTL may also be made of copper phthalocyanine (CuPc).

The red light-emitting material layer REML may be disposed on the hole transport layer HTL in the first sub-pixel SP1. The green light-emitting material layer GEML may be commonly disposed in the first sub-pixel SP1 and the second sub-pixel SP2. The green light-emitting material layer GEML may be disposed on the red light-emitting material layer REML in the first sub-pixel SP1, and may be disposed on the hole transport layer HTL in the second sub-pixel SP2. The blue light-emitting material layer BEML may be commonly disposed in the first sub-pixel SP1, the second sub-pixel SP2, and the third sub-pixel SP3. The blue light-emitting material layer BEML may be disposed on the green light-emitting material layer REML in each of the first sub-pixel SP1 and the second sub-pixel SP2, and may be disposed on the hole transport layer HTL in the third sub-pixel SP3. Each of the red light-emitting material layer REML, the green light-emitting material layer REML, and the blue light-emitting material layer BEML may be made of an organic material.

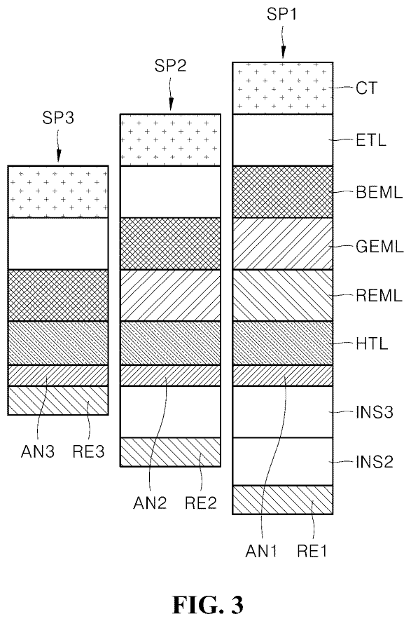

The light-emission stack of the first to third sub-pixels SP1, SP2, and SP3 will be described later with reference to FIG. 3.

An electron transport layer ETL may be commonly disposed in the first sub-pixel SP1, the second sub-pixel SP2, and the third sub-pixel SP3. The electron transport layer ETL may be disposed on the blue light-emitting material layer BEML. The electron transport layer ETL may be made of an organic material. The electron transport layer ETL may be made of carbazole, oxadiazole, triazole, phenanthroline, benzoxazole, benzothiazole, or etc. However, embodiments of the present disclosure are not limited thereto.

The cathode electrode CT may be disposed on the electron transport layer ETL. The cathode electrode CT may also be commonly disposed in the first to third sub-pixels SP1, SP2, and SP3.

The cathode electrode CT may be made of a semi-transparent conductive material. The cathode electrode CT may be made of a metal material such as magnesium (Mg), silver (Ag), or an alloy of magnesium (Mg) and silver (Ag). The cathode electrode CT may be formed in a form of a thin film having a thickness of several nm to several tens of nm. Accordingly, as the reflection and re-reflection of light repeatedly occur between the cathode electrode CT and the first to third reflective electrodes RE1, RE2, and RE3, a micro cavity effect may be obtained in the first to third sub-pixels SP1, SP2, and SP3.

According to an embodiment of the present disclosure, since all of a first spacing between the first reflective electrode RE1 and the cathode electrode CT in the first sub-pixel SP1, a second spacing between the second reflective electrode RE2 and the cathode electrode CT in the second sub-pixel SP2, and a third spacing between the third reflective electrode RE3 and the cathode electrode CT in the third sub-pixel SP3 may be configured to be different from each other, light extraction efficiency and color purity of light of different colors, for example, red light, green light, and blue light, may be improved in the first to third sub-pixels SP1, SP2, and SP3 due to the micro-cavity effect.

The encapsulation layer ENC may be disposed on the cathode electrode CT (FIG. 2). The encapsulation layer ENC may protect the red light-emitting material layer REML, the green light-emitting material layer GEML, and the blue light-emitting material layer BEML from external moisture. The encapsulation layer ENC may include inorganic encapsulation layers and organic encapsulation layers which are alternately stacked on top of each other. The inorganic encapsulation layer may be made of one selected from aluminum oxide (AlₓO_{y}), silicon oxide (SiOₓ), silicon nitride (SiNₓ), silicon oxynitride (SiON), etc.

FIG. 3 schematically illustrates a stack structure of each of sub-pixels of a display device according to an embodiment of the present disclosure.

Referring to FIG. 3, a light-emitting stack disposed in the first sub-pixel SP1 may include the first reflective electrode RE1, the first anode electrode AN1 disposed on the first reflective electrode RE1, the second insulating layer INS2 and the third insulating layer INS3 disposed between the first reflective electrode RE1 and the first anode electrode AN1, the hole transport layer HTL disposed on the first anode electrode AN1, the red light-emitting material layer REML, the green light-emitting material layer GEML and the blue light-emitting material layer BEML sequentially stacked on the hole transport layer HTL, the electron transport layer ETL disposed on the blue light-emitting material layer BEML, and the cathode electrode CT disposed on the electron transport layer ETL.

The red light-emitting material layer REML may include a red host and a red dopant. The green light-emitting material layer GEML may include a green host and a green dopant. The blue light-emitting material layer BEML may include a blue host and a blue dopant.

A process in which red light is generated in the first sub-pixel SP1 will be described. In the first sub-pixel SP1, energy may be transferred from the blue light-emitting material layer BEML to the green light-emitting material layer GEML, and energy may be transferred from the green light-emitting material layer GMEL to the red light-emitting material layer REML.

When excitons are generated in the red host, the red host emits energy. The red dopant may absorb energy emitted from the red host, and light emission may occur due to recombination of electrons and holes in the red dopant.

When excitons are generated in the green host, the green host emits energy. The green dopant absorbs the energy emitted from the green host and then emits the energy again. The red host absorbs the energy emitted from the green dopant again and then emits the energy again. The red dopant may absorb energy emitted from the red host, and light emission may occur due to recombination of electrons and holes in the red dopant.

When excitons are generated in the blue host, the blue host emits energy. Energy emitted from the blue host is absorbed by the blue dopant which in turn emits the energy again. The green host absorbs the energy emitted from the blue dopant again and then emits the energy again. The green dopant absorbs the energy emitted from the green host and then emits the energy again. The red host absorbs the energy emitted from the green dopant again and then emits the energy again. The red dopant may absorb energy emitted from the red host, and light emission may occur due to recombination of electrons and holes in the red dopant.

The following conditions are required for the energy transfer as described above.

The emission spectrum of the blue dopant and the absorption spectrum of the green host may at least partially overlap with each other. The long wavelength edge of the emission spectrum of the blue dopant may have a longer wavelength than the short wavelength edge of the absorption spectrum of the green host. The emission spectrum of the green dopant and the absorption spectrum of the red host may at least partially overlap with each other. The long wavelength edge of the emission spectrum of the green dopant may have a longer wavelength than the short wavelength edge of the absorption spectrum of the red host.

Each of the red host, the green host, and the blue host may be embodied as a single host or a mixed host in which an N-type host and a P-type host are mixed with each other. When each of the red host, the green host, and the blue host is embodied as the mixed host, the material of the P-type host may be included in an amount of 20 wt % or smaller of the total amount of the host material. The hole mobility of the P-type host may be greater than or equal to 1×10⁻⁶ cm²/V·sec and lower than 1×10⁻⁴ cm²/V·sec. The electron mobility of the N-type host may be 1×10⁻⁴ cm²/V·sec or greater.

The second insulating layer INS2 and the third insulating layer INS3 disposed between the first reflective electrode RE1 and the first anode electrode AN1 may act as cavity control layers of the first sub-pixel SP1.

Red light generated in the red light-emitting material layer REML may be emitted to the outside through the cathode electrode CT. Light extraction efficiency and color purity of red light generated from the red light-emitting material layer REML may be improved due to the micro-cavity effect between the first reflective electrode RE1 and the cathode electrode CT.

The light-emitting stack disposed in the second sub-pixel SP2 may include the second reflective electrode RE2, the second anode electrode AN2 disposed on the second reflective electrode RE2, the third insulating layer INS3 disposed between the second reflective electrode RE2 and the second anode electrode AN2, the hole transport layer HTL disposed on the second anode electrode AN2, the green light-emitting material layer GEML and the blue light-emitting material layer BEML sequentially deposited on the hole transport layer HTL, the electron transport layer ETL disposed on the blue light-emitting material layer BEML, and the cathode electrode CT disposed on the electron transport layer ETL.

The green light-emitting material layer GEML may include a green host and a green dopant. The blue light-emitting material layer BEML may include a blue host and a blue dopant. The green light-emitting material layer GEML and the blue light-emitting material layer BEML disposed in the second sub-pixel SP2 may be respectively the same as the green light-emitting material layer GEML and the blue light-emitting material layer BEML disposed in the first sub-pixel SP1.

A process in which green light is generated in the second sub-pixel SP2 will be described. Energy may be transferred from the blue light-emitting material layer BMEL to the green light-emitting material layer GEML in the second sub-pixel SP2.

When excitons are generated in the green host, the green host emits energy. The green dopant absorbs the energy emitted from the green host, and light emission occurs under recombination of electrons and holes in the green dopant.

When excitons are generated in the blue host, the blue host emits energy. Energy emitted from the blue host is absorbed by the blue dopant which in turn emits the energy again. The green host absorbs the energy emitted from the blue dopant again and then emits the energy again. The green dopant absorbs the energy emitted from the green host, and light emission occurs under recombination of electrons and holes in the green dopant.

The third insulating layer INS3 disposed between the second reflective electrode RE2 and the second anode electrode AN2 may act as a cavity control layer of the second sub-pixel SP2.

Green light generated in the green light-emitting material layer GEML may be emitted to the outside through the cathode electrode CT. Light extraction efficiency and color purity of green light generated from the green light-emitting material layer GEML may be improved due to the micro-cavity effect between the second reflective electrode RE2 and the cathode electrode CT.

The light-emitting stack disposed in the third sub-pixel SP3 may include the third reflective electrode RE3, the third anode electrode AN3 disposed on the third reflective electrode RE3, the hole transport layer HTL disposed on the third anode electrode AN3, the blue light-emitting material layer BEML disposed on the hole transport layer HTL, the electron transport layer ETL disposed on the blue light-emitting material layer BEML, and the cathode electrode CT disposed on the electron transport layer ETL.

The blue light-emitting material layer BEML may include a blue host and a blue dopant. The blue light-emitting material layer BEML disposed in the third sub-pixel SP3 may be the same as the blue light-emitting material layer BEML disposed in the first sub-pixel SP1 and the second sub-pixel SP2.

A process in which blue light is generated in the third sub-pixel SP3 will be described.

When excitons are generated in the blue host, the blue host emits energy. The blue dopant absorbs the energy emitted from the blue host, and light emission occurs under recombination of electrons and holes in the blue dopant.

Blue light generated from the blue light-emitting material layer BEML may be emitted to the outside through the cathode electrode CT. Light extraction efficiency and color purity of blue light generated in the blue light-emitting material layer BEML may be improved due to the micro-cavity effect between the third reflective electrode RE3 and the cathode electrode CT.

In order to generate an optimal micro cavity effect in each sub-pixel, the spacing between each reflective electrode and the cathode electrode CT may be adjusted per each of the sub-pixels. Accordingly, a spacing between the first anode electrode AN1 and the first reflective electrode RE1 may be greater than a spacing between the second anode electrode AN2 and the second reflective electrode RE2.

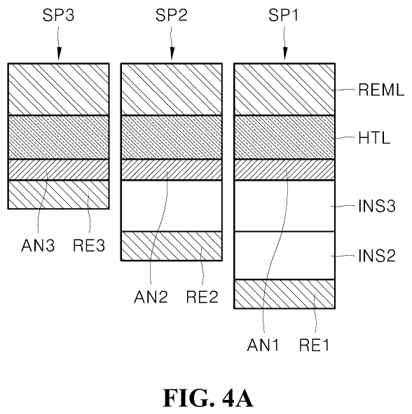

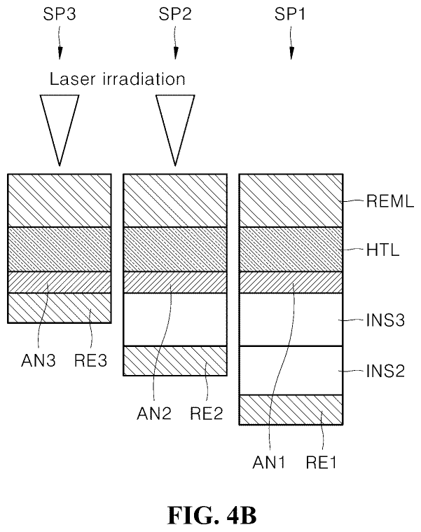

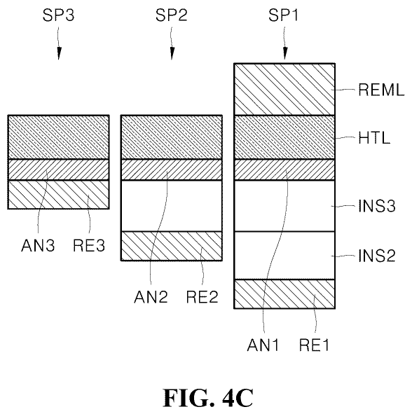

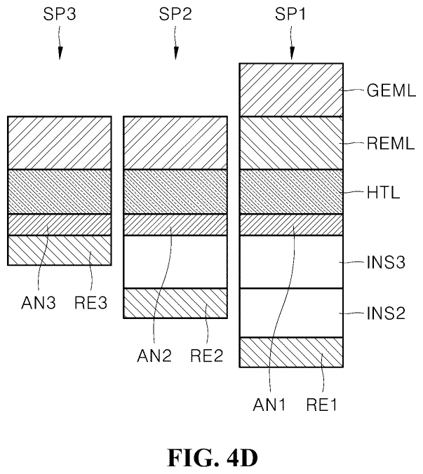

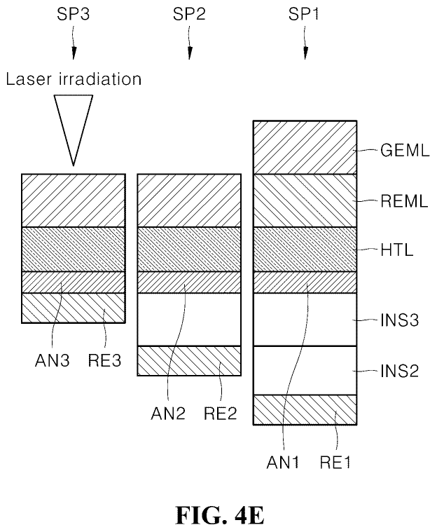

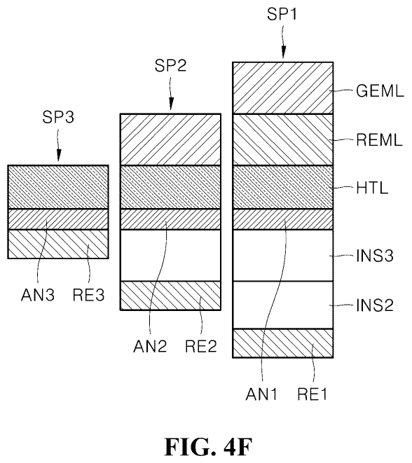

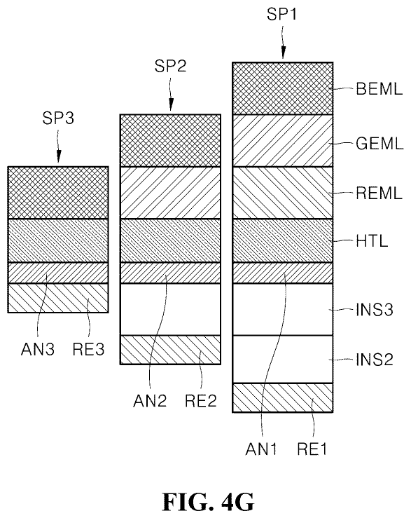

FIGS. 4A to 4G schematically illustrate a method for manufacturing a display device according to an embodiment of the present disclosure. FIGS. 4A to 4G schematically illustrate a method for manufacturing the display device as illustrated in FIG. 3.

Referring to FIG. 4A, the backplane substrate BPN (FIG. 2) including the first anode electrode AN1 disposed in the first sub-pixel SP1, the second anode electrode AN2 disposed in the second sub-pixel SP2, and the third anode electrode AN3 disposed in the third sub-pixel SP3 may be prepared. Then, the hole transport layer HTL and the red light-emitting material layer REML may be commonly deposited in the first to third sub-pixels SP1, SP2, and SP3 and on the first to third anode electrodes AN1, AN2, and AN3 of the backplane substrate BPN. After the hole transport layer HTL is first deposited on the first to third anode electrodes AN1, AN2, and AN3 of the backplane substrate BPN (FIG. 2), the red light-emitting material layer REML may be deposited on the hole transport layer HTL.

Referring to FIGS. 4B and 4C, the red light-emitting material layer REML may be selectively removed from the second sub-pixel SP2 and the third sub-pixel SP3 by irradiating laser to the second sub-pixel SP2 and the third sub-pixel SP3. Accordingly, the red light-emitting material layer REML may be formed on the hole transport layer HTL in the first sub-pixel SP1. The wavelength of the laser may be any wavelength. In one example, the laser having a wavelength of UV (355 nm), visible light (532 nm), or infrared (1064 nm) may be used. In addition, a nanosecond laser, a picosecond laser, and a femtosecond laser may be used to secure selective thermal properties of the hole transport layer HTL and the red light-emitting material layer REML.

Referring to FIG. 4D, the green light-emitting material layer GEML may be commonly deposited in the first to third sub-pixels SP1, SP2, and SP3. In the second and third sub-pixels SP2 and SP3, the green light-emitting material layer GEML may be deposited on the hole transport layer HTL, and in the first sub-pixel SP1, the green light-emitting material layer GEML may be deposited on the red light-emitting material layer REML.

Referring to FIGS. 4E and 4F, the green light-emitting material layer GEML may be selectively removed from the third sub-pixel SP3 by irradiating laser to the third sub-pixel SP3. Accordingly, the green light-emitting material layer GEML may be formed on the hole transport layer HTL in the second sub-pixel SP2, and the green light-emitting material layer GEML may be formed on the red light-emitting material layer REML in the first sub-pixel SP1. The wavelength of the laser may be any wavelength. In one example, the laser having a wavelength of UV (355 nm), visible light (532 nm), or infrared (1064 nm) may be used. In addition, a nanosecond laser, a picosecond laser, and a femtosecond laser may be used to secure selective thermal properties of the hole transport layer HTL and the green light-emitting material layer GEML.

Referring to FIG. 4G, the blue light-emitting material layer BEML may be commonly deposited in the first to third sub-pixels SP1, SP2, and SP3. The blue light-emitting material layer BEML may be deposited on the hole transport layer HTL in the third sub-pixel SP3, and the blue light-emitting material layer BEML may be deposited on the green light-emitting material layer GEML in each of the first and second sub-pixels SP1 and SP2.

Referring back to FIG. 3, the electron transport layer ETL and the cathode electrode CT may be sequentially deposited in the first to third sub-pixels SP1, SP2, and SP3.

In an embodiment of the present disclosure, the hole transport layer HTL made of the inorganic material may be applied, such that the light-emitting material layers made of the organic material may be selectively removed via the laser irradiation using a difference in thermal properties between the inorganic material and the organic material. In addition, in an embodiment of the present disclosure, the hole transport layer HTL made of the inorganic material may be applied, such that deterioration of the hole transport layer HTL due to irradiation of the laser may be reduced or prevented.

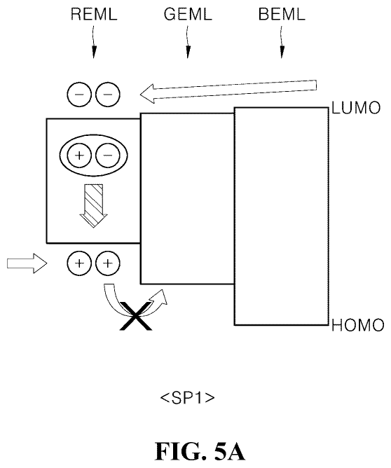

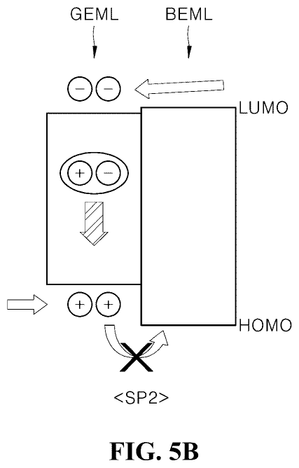

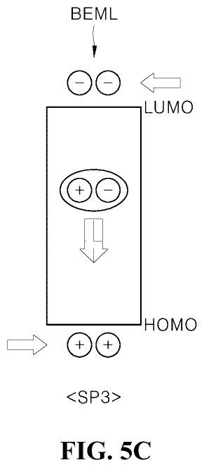

FIGS. 5A to 5C illustrate energy levels of sub-pixels of a display device according to an embodiment of the present disclosure. FIGS. 5A to 5C schematically illustrate energy levels of light-emitting material layers of the first to third sub-pixels SP1, SP2, and SP3 of the display device as illustrated in FIG. 3.

Referring to FIG. 5A, in order to make it difficult for holes injected from the hole transport layer HTL to migrate from the red light-emitting material layer REML to the green light-emitting material layer GEML in the first sub-pixel SP1, it is preferable that a highest occupied molecular orbital (HOMO) level of the red host of the red light-emitting material layer REML is higher than a highest occupied molecular orbital (HOMO) level of the green host of the green light-emitting material layer GEML, and a highest occupied molecular orbital (HOMO) level of the red dopant of the red light-emitting material layer REML is higher than a highest occupied molecular orbital (HOMO) level of the green dopant of the green light-emitting material layer GEML. For example, a highest occupied molecular orbital (HOMO) level of each of the host and the dopant of the red light-emitting material layer REML may be higher than a highest occupied molecular orbital (HOMO) level of each of the host and the dopant of the green light-emitting material layer GEML by 0.3 eV or greater.

In order to make it difficult for holes to migrate from the green light-emitting material layer GEML to the blue light-emitting material layer BEML, it is preferable that a highest occupied molecular orbital (HOMO) level of the green host of the green light-emitting material layer GEML is higher than a highest occupied molecular orbital (HOMO) level of the blue host of the blue light-emitting material layer BEML, and a highest occupied molecular orbital (HOMO) level of the green dopant of the green light-emitting material layer GEML is higher than a highest occupied molecular orbital (HOMO) level of the blue dopant of the blue light-emitting material layer BEML. For example, a highest occupied molecular orbital (HOMO) level of each of the green host and the green dopant of the green light-emitting material layer GEML may be higher than a highest occupied molecular orbital (HOMO) level of each of the blue host and the blue dopant of the blue light-emitting material layer BEML by 0.3 eV or greater.

In order to allow electrons injected from the electron transport layer ETL to easily migrate from the blue light-emitting material layer BEML to the green light-emitting material layer GEML, a lowest unoccupied molecular orbital (LUMO) level of the green host of the green light-emitting material layer GEML is lower than a lowest unoccupied molecular orbital (LUMO) level of the blue host of the blue light-emitting material layer BEML, and a lowest unoccupied molecular orbital (LUMO) level of the green dopant of the green light-emitting material layer GEML is lower than a lowest unoccupied molecular orbital (LUMO) level of the blue dopant of the blue light-emitting material layer BEML. In an embodiment, a lowest unoccupied molecular orbital (LUMO) level of each of the host and the dopant of the green light-emitting material layer GEML may be equal to a lowest unoccupied molecular orbital (LUMO) level of each of the host and the dopant of the blue light-emitting material layer BEML.

In order to allow the electrons to easily migrate from the green light-emitting material layer GEML to the red light-emitting material layer REML, a lowest unoccupied molecular orbital (LUMO) level of a red host of the red light-emitting material layer REML may be lower than a lowest unoccupied molecular orbital (LUMO) level of the green host of the green light-emitting material layer GEML, and a lowest unoccupied molecular orbital (LUMO) level of a red dopant of the red light-emitting material layer REML may be lower than a lowest unoccupied molecular orbital (LUMO) level of the green dopant of the green light-emitting material layer GEML. In an embodiment, a lowest unoccupied molecular orbital (LUMO) level of each of the host and the dopant of the red light-emitting material layer REML may be equal to a lowest unoccupied molecular orbital (LUMO) level of each of the host and the dopant of the green light-emitting material layer GEML.

Accordingly, recombination of electrons and holes may mainly occur in the red light-emitting material layer REML of the first sub-pixel SP1, and red light may be emitted from the light-emitting stack of the first sub-pixel SP1.

Referring to FIG. 5B, in the second sub-pixel SP2, in order to make it difficult for holes injected from the hole transport layer HTL to migrate from the green light-emitting material layer GEML to the blue light-emitting material layer BEML, a highest occupied molecular orbital (HOMO) level of the green host of the green light-emitting material layer GEML is higher than a highest occupied molecular orbital (HOMO) level of the blue host of the blue light-emitting material layer BEML, and a highest occupied molecular orbital (HOMO) level of the green dopant of the green light-emitting material layer GEML is higher than a highest occupied molecular orbital (HOMO) level of the blue dopant of the blue light-emitting material layer BEML. For example, a highest occupied molecular orbital (HOMO) level of each of the green host and the green dopant of the green light-emitting material layer GEML may be higher than a highest occupied molecular orbital (HOMO) level of each of the blue host and the blue dopant of the blue light-emitting material layer BEML by 0.3 eV or greater.

In order to allow the electrons to easily migrate from the blue light-emitting material layer BEML to the green light-emitting material layer GEML, a lowest unoccupied molecular orbital (LUMO) level of the green host of the green light-emitting material layer GEML may be lower than a lowest unoccupied molecular orbital (LUMO) level of the blue host of the blue light-emitting material layer BEML, and a lowest unoccupied molecular orbital (LUMO) level of the green dopant of the green light-emitting material layer GEML may be lower than a lowest unoccupied molecular orbital (LUMO) level of the blue dopant of the blue light-emitting material layer BEML. In an embodiment, a lowest unoccupied molecular orbital (LUMO) level of each of the green host and the green dopant of the green light-emitting material layer GEML may be equal to a lowest unoccupied molecular orbital (LUMO) level of each of the blue host and the blue dopant of the blue light-emitting material layer BEML.

Accordingly, recombination of electrons and holes may mainly occur in the green light-emitting material layer GEML of the second sub-pixel SP2, and green light may be emitted from the light-emitting stack of the second sub-pixel SP2.

Referring to FIG. 5C, since only the blue light-emitting material layer BEML is disposed in the third sub-pixel SP3, recombination of electrons and holes may occur in the blue light-emitting material layer BEML of the third sub-pixel SP3, and blue light may be emitted from the light-emitting stack of the third sub-pixel SP3.

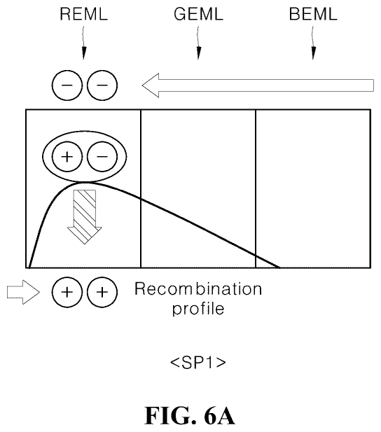

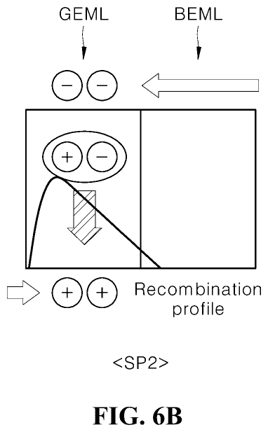

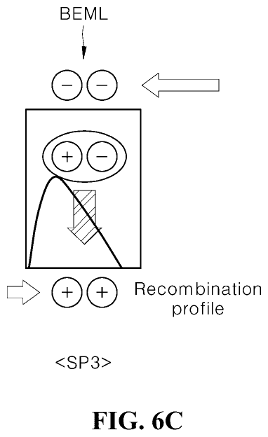

FIGS. 6A to 6C illustrate a recombination profile of each of sub-pixels of a display device according to an embodiment of the present disclosure.

Referring to FIG. 6A, in the first sub-pixel SP1, in addition to the design of the HOMO level and the LUMO level of each of the red, green, and blue light-emitting material layers REML, GEML, and BEML, the electron mobility in each of the red, green, and blue light-emitting material layers REML, GEML, and BEML is designed be higher than the hole mobility in each of the red, green, and blue light-emitting material layers REML, GEML, and BEML, so that recombination of electrons and holes may mainly occur in the red light-emitting material layer REML in the first sub-pixel SP1. In the first sub-pixel SP1, a small amount of recombination of electrons and holes may also occur in the green light-emitting material layer GEML, but light is finally emitted from the red light-emitting material layer REML due to energy transition. Accordingly, red light may be emitted from the light emission stack of the first sub-pixel SP1.

Referring to FIG. 6B, in the second sub-pixel SP2, in addition to the design of the HOMO level and the LUMO level of each of the light-emitting material layers GEML and BEML, the electron mobility may be designed to be higher than the hole mobility in each of the light-emitting material layers GEML and BEML, such that the greater amount of the recombination of electrons and holes may occur in the green light-emitting material layer GEML in the second sub-pixel SP2. Accordingly, green light may be emitted from the light emission stack of the second sub-pixel SP2.

Referring to FIG. 6C, recombination of electrons and holes may occur in the blue light-emitting material layer BEML in the third sub-pixel SP3. Accordingly, blue light may be emitted from the light emission stack of the third sub-pixel SP3.

According to an embodiment of the present disclosure, there may be provided a display device including a red light-emitting element, a green light-emitting element, and a blue light-emitting element, in which a red light-emitting material layer, a green light-emitting material layer, and a blue light-emitting material layer are stacked in a first sub-pixel, a green light-emitting material layer, and a blue light-emitting material layer are stacked in a second sub-pixel, and a blue light-emitting material layer is disposed in a third sub-pixel, and energy is allowed to be transferred from the blue light-emitting material layer to the green light-emitting material layer and from the green light-emitting material layer to the red light-emitting material layer, thereby providing a high-resolution image to a user and reducing power consumption.

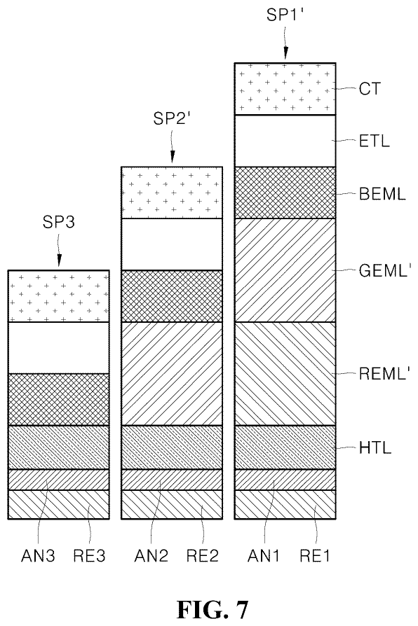

FIG. 7 schematically illustrates a stack structure of each of sub-pixels of a display device according to an embodiment of the present disclosure.

Referring to FIG. 7, a light-emitting stack disposed in a first sub-pixel SP1′ may include a first reflective electrode RE1, a first anode electrode AN1 disposed on the first reflective electrode RE1, a hole transport layer HTL disposed on the first anode electrode AN1, a red light-emitting material layer REML', a green light-emitting material layer GEML', and a blue light-emitting material layer BEML sequentially deposited on the hole transport layer HTL, an electron transport layer ETL disposed on the blue light-emitting material layer BEML, and a cathode electrode CT disposed on the electron transport layer ETL.

Unlike the display device of the embodiment illustrated in FIG. 3, the display device of the embodiment of FIG. 7 may not include the second insulating layer INS2 and the third insulating layer INS3, that is, the cavity control layer between the first reflective electrode RE1 and the first anode electrode AN1 in the first sub-pixel SP1′. Accordingly, each of the red light-emitting material layer REML′ and the green light-emitting material layer GEML′ of the display device of FIG. 7 may be thicker than each of the red light-emitting material layer REML and the green light-emitting material layer GEML of the display device of FIG. 3 in order to implement the micro-cavity effect in the first sub-pixel SP1′. The red light-emitting material layer REML′ of the display device of FIG. 7 may be thicker than the red light-emitting material layer REML of the display device of FIG. 3 by the thickness of the second insulating layer INS2. The green light-emitting material layer GEML′ of the display device of FIG. 7 may be thicker than the green light-emitting material layer GEML of the display device of FIG. 3 by the thickness of the third insulating layer INS3.

The red light generated in the red light-emitting material layer REML′ may be emitted to the outside through the cathode electrode CT. Light extraction efficiency and color purity of the red light generated in the red light-emitting material layer REML′ may be improved due to the micro-cavity effect between the first reflective electrode RE1 and the cathode electrode CT.

Alight-emitting stack disposed in the second sub-pixel SP2′ may include a second reflective electrode RE2, a second anode electrode AN2 disposed on the second reflective electrode RE2, a hole transport layer HTL disposed on the second anode electrode AN2, a green light-emitting material layer GEML′ and a blue light-emitting material layer BEML sequentially deposited on the hole transport layer HTL, an electron transport layer ETL disposed on the blue light-emitting material layer BEML, and a cathode electrode CT disposed on the electron transport layer ETL.

Unlike the display device of the embodiment illustrated in FIG. 3, the display device of the embodiment of FIG. 7 may not include the third insulating layer INS3, that is, the cavity control layer between the second reflective electrode RE2 and the second anode electrode AN2 in the second sub-pixel SP2′. Accordingly, the green light-emitting material layer GEML′ of the display device of FIG. 7 may be thicker than the green light-emitting material layer GEML of the display device of FIG. 3 in order to implement the micro-cavity effect in the second sub-pixel SP2′. The green light-emitting material layer GEML′ of the display device of FIG. 7 may be thicker than the green light-emitting material layer GEML of the display device of FIG. 3 by the thickness of the third insulating layer INS3.

The green light generated in the green light-emitting material layer GEML′ may be emitted to the outside through the cathode electrode CT. Light extraction efficiency and color purity of green light generated in the green light-emitting material layer GEML′ may be improved due to the micro-cavity effect between the first reflective electrode RE1 and the cathode electrode CT.

The light-emitting stack disposed in the third sub-pixel SP3 may include a third reflective electrode RE3, a third anode electrode AN3 disposed on the third reflective electrode RE3, a hole transport layer HTL disposed on the third anode electrode AN3, a blue light-emitting material layer BEML disposed on the hole transport layer HTL, an electron transport layer ETL disposed on the blue light-emitting material layer BEML, and a cathode electrode CT disposed on the electron transport layer ETL.

The thickness of the blue light-emitting material layer BEML of the display device of FIG. 7 may be equal to the thickness of the blue light-emitting material layer BEML of FIG. 3. In the first sub-pixel SP1′, each of the red light-emitting material layer REML′ and the green light-emitting material layer GEML′ may be thicker than the blue light-emitting material layer BEML. In the second sub-pixel SP2′, the green light-emitting material layer GEML′ may be thicker than the blue light-emitting material layer BEML.

According to an embodiment of the present disclosure, realized is a display device which has a red light-emitting element, a green light-emitting element, a blue light-emitting element, in which a red light-emitting material layer, a green light-emitting material layer, and a blue light-emitting material layer are stacked in a first sub-pixel, a green light-emitting material layer, and a blue light-emitting material layer are stacked in a second sub-pixel, a blue light-emitting material layer is disposed in a third sub-pixel, and energy is allowed to transfer from the blue light-emitting material layer to the green light-emitting material layer, and from the green light-emitting material layer to the red light-emitting material layer, thereby providing a high resolution image and reducing power consumption.

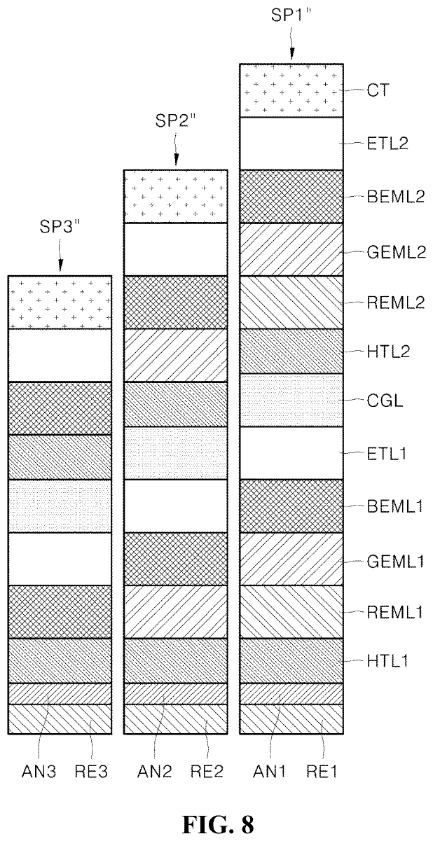

FIG. 8 schematically illustrates a stack structure of each of sub-pixels of a display device according to an embodiment of the present disclosure.

Referring to FIG. 8, a light-emitting stack disposed in a first sub-pixel SP1″ includes a first reflective electrode RE1, a first anode electrode AN1 disposed on the first reflective electrode RE1, a first hole transport layer HTL1 disposed on the first anode electrode AN1, a first red light-emitting material layer REML1, a first green light-emitting material layer GEML1, and a first blue light-emitting material layer BEML1 sequentially deposited on the first hole transport layer HTL1, a first electron transport layer ETL1 disposed on the first blue light-emitting material layer BEML1, a charge generation layer CGL disposed on the first electron transport layer ETL1, a second hole transport layer HTL2 disposed on the charge generation layer CGL, a second red light-emitting material layer REML2, a second green light-emitting material layer GEML2, and a second blue light-emitting material layer BEML2 sequentially deposited on the second hole transport layer HTL2, a second electron transport layer ETL2 disposed on the second blue light-emitting material layer BEML2, and a cathode electrode CT disposed on the second electron transport layer ETL2.

A light-emitting stack disposed in a second sub-pixel SP2″ includes a second reflective electrode RE2, a second anode electrode AN2 disposed on the second reflective electrode RE2, a first hole transport layer HTL1 disposed on the second anode electrode AN2, a first green light-emitting material layer GEML1 and a first blue light-emitting material layer BEML1 sequentially deposited on the first hole transport layer HTL1, a first electron transport layer ETL1 disposed on the first blue light-emitting material layer BEML1, a charge generation layer CGL disposed on the first electron transport layer ETL1, a second hole transport layer HTL2 disposed on the charge generation layer CGL, a second green light-emitting material layer GEML2 and a second blue light-emitting material layer BEML2 sequentially deposited on the second hole transport layer HTL2, a second electron transport layer ETL2 disposed on the second blue light-emitting material layer BEML2, and a cathode electrode CT disposed on the second electron transport layer ETL2.

A light-emitting stack disposed in a third sub-pixel SP3″ includes a third reflective electrode RE3, a third anode electrode AN3 disposed on the third reflective electrode RE3, a first hole transport layer HTL1 disposed on the third anode electrode AN3, a first blue light-emitting material layer BEML1 disposed on the first hole transport layer HTL1, a first electron transport layer ETL1 disposed on the first blue light-emitting material layer BEML1, a charge generation layer CGL disposed on the first electron transport layer ETL1, a second hole transport layer HTL2 disposed on the charge generation layer CGL, a second blue light-emitting material layer BEML2 disposed on the second hole transport layer HTL2,a second electron transport layer ETL2 disposed on the second blue light-emitting material layer BEML2, and a cathode electrode CT disposed on the second electron transport layer ETL2.

Each of the first and second hole transport layers HTL1 and HTL2 may be the same as the hole transport layer HTL of FIG. 3. Each of the first and second red light-emitting material layers REML1 and REML2 may be the same as the red light-emitting material layer REML of FIG. 3. Each of the first and second green light-emitting material layers GEML1 and GEML2 may be the same as the green light-emitting material layer GEML of FIG. 3. Each of the first and second blue light-emitting material layers BEML1 and BEML2 may be the same as the blue light-emitting material layer BEML of FIG. 3.

In FIG. 8, the cavity control layer is not disposed between the first reflective electrode RE1 and the first anode electrode AN1 of the first sub-pixel SP1″ and between the second reflective electrode RE2 and the second anode electrode AN2 of the second sub-pixel SP2″. In an embodiment, the second insulating layer INS2 and the third insulating layer INS3 may be disposed between the first reflective electrode RE1 and the first anode electrode AN1 of the first sub-pixel SP1″, and the third insulating layer INS3 may be disposed between the second reflective electrode RE2 and the second anode electrode AN2 of the second sub-pixel SP2″.

According to an embodiment of the present disclosure, there may be provided a display device having a red light-emitting element, a green light-emitting element, and a blue light-emitting element, in which a red light-emitting material layer, a green light-emitting material layer, and a blue light-emitting material layer are stacked in a first sub-pixel, a green light-emitting material layer, and a blue light-emitting material layer are stacked in a second sub-pixel, and a blue light-emitting material layer is disposed in a third sub-pixel, and energy is allowed to be transferred from the blue light-emitting material layer to the green light-emitting material layer and from the green light-emitting material layer to the red light-emitting material layer, thereby providing a high-resolution image to a user and reducing power consumption.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

What is claimed is:

1. A display device comprising:
a substrate; and
a first sub-pixel, a second sub-pixel, and a third sub-pixel, each of which is disposed on the substrate,
wherein the first sub-pixel comprises:
a first anode electrode disposed on the substrate; and
a hole transport layer, a red light-emitting material layer, a green light-emitting material layer, a blue light-emitting material layer, and an electron transport layer sequentially stacked on the first anode electrode,
wherein the second sub-pixel comprises:
a second anode electrode disposed on the substrate; and
a hole transport layer, a green light-emitting material layer, a blue light-emitting material layer, and an electron transport layer sequentially stacked on the second anode electrode, and
wherein the third sub-pixel comprises:
a third anode electrode disposed on the substrate; and
a hole transport layer, a blue light-emitting material layer, and an electron transport layer sequentially stacked on the third anode electrode.

2. The display device of claim 1, wherein the hole transport layer in each of the first sub-pixel to the third sub-pixel is made of an inorganic material.

3. The display device of claim 2, wherein the display device further comprises:
a first reflective electrode disposed between the first anode electrode and the substrate; and
a second reflective electrode disposed between the second anode electrode and the substrate.

4. The display device of claim 3, wherein a spacing between the first anode electrode and the first reflective electrode is greater than a spacing between the second anode electrode and the second reflective electrode.

5. The display device of claim 3, wherein a first insulating layer and a second insulating layer are disposed between the first anode electrode and the first reflective electrode, and
wherein the second insulating layer is disposed between the second anode electrode and the second reflective electrode.

6. The display device of claim 3, wherein the display device further comprises a third reflective electrode disposed between the third anode electrode and the substrate.

7. The display device of claim 1, wherein each of the red light-emitting material layer and the green light-emitting material layer is thicker than the blue light-emitting material layer in the first sub-pixel, and
wherein the green light-emitting material layer is thicker than the blue light-emitting material layer in the second sub-pixel.

8. The display device of claim 1, wherein the hole transport layer in each of the first sub-pixel to the third sub-pixel is a first hole transport layer, the red light-emitting material layer in each of the first sub-pixel to the third sub-pixel is a first red light-emitting material layer, the green light-emitting material layer in each of the first sub-pixel to the third sub-pixel is a first green light-emitting material layer, the blue light-emitting material layer in each of the first sub-pixel to the third sub-pixel is a first blue light-emitting material layer, and the electron transport layer in each of the first sub-pixel to the third sub-pixel is a first electron transport layer,
wherein the first sub-pixel further comprises:
a charge generation layer disposed on the first electron transport layer; and
a second hole transport layer, a second red light-emitting material layer, a second green light-emitting material layer, a second blue light-emitting material layer, and a second electron transport layer sequentially stacked on the charge generation layer of the first sub-pixel,
wherein the second sub-pixel further comprises:
a charge generation layer disposed on the first electron transport layer; and
a second hole transport layer, a second green light-emitting material layer, a blue light-emitting material layer, and a second electron transport layer sequentially stacked on the charge generation layer of the second sub-pixel, and
wherein the third sub-pixel further comprises:
a charge generation layer disposed on the first electron transport layer; and
a second hole transport layer, a second blue light-emitting material layer, and a second electron transport layer sequentially stacked on the charge generation layer of the third sub-pixel.

9. The display device of claim 1, wherein an emission spectrum of a blue dopant of the blue light-emitting material layer at least partially overlaps with an absorption spectrum of a green host of the green light-emitting material layer, and
wherein an emission spectrum of a green dopant of the green light-emitting material layer at least partially overlaps with an absorption spectrum of a red host of the red light-emitting material layer.

10. The display device of claim 1, wherein a highest occupied molecular orbital (HOMO) level of a red host of the red light-emitting material layer is higher than a highest occupied molecular orbital (HOMO) level of a green host of the green light-emitting material layer, and
wherein the highest occupied molecular orbital (HOMO) level of the green host of the green light-emitting material layer is higher than a highest occupied molecular orbital (HOMO) level of a blue host of the blue light-emitting material layer.

11. The display device of claim 1, wherein a lowest unoccupied molecular orbital (LUMO) level of a red host of the red light-emitting material layer is lower than a lowest unoccupied molecular orbital (LUMO) level of a green host of the green light-emitting material layer, and
wherein the lowest unoccupied molecular orbital (LUMO) level of the green host of the green light-emitting material layer is lower than a lowest unoccupied molecular orbital (LUMO) level of a blue host of the blue light-emitting material layer.

12. A method for manufacturing a display device comprising a first sub-pixel, a second sub-pixel, and a third sub-pixel, the method comprising:
providing a backplane substrate comprising a first anode electrode disposed in the first sub-pixel, a second anode electrode disposed in the second sub-pixel, and a third anode electrode disposed in the third sub-pixel;
depositing a hole transport layer on the first anode electrode, the second anode electrode, and the third anode electrode in the first sub-pixel, the second sub-pixel, and the third sub-pixel;
depositing a red light-emitting material layer on the hole transport layer in the first sub-pixel, the second sub-pixel, and the third sub-pixel;
removing the red light-emitting material layer from each of the second sub-pixel and the third sub-pixel;
depositing a green light-emitting material layer in the first sub-pixel, the second sub-pixel, and the third sub-pixel;
removing the green light-emitting material layer from the third sub-pixel; and
depositing a blue light-emitting material layer in the first sub-pixel, the second sub-pixel, and the third sub-pixel.

13. The method of claim 12, wherein the hole transport layer is made of an inorganic material.

14. The method of claim 12, wherein each of the removing of the red light-emitting material layer and the removing of the green light-emitting material layer is performed by laser irradiation.

15. The method of claim 12, wherein an emission spectrum of a blue dopant of the blue light-emitting material layer at least partially overlaps with an absorption spectrum of a green host of the green light-emitting material layer, and
wherein an emission spectrum of a green dopant of the green light-emitting material layer at least partially overlaps with an absorption spectrum of a red host of the red light-emitting material layer.

16. The method of claim 12, wherein a highest occupied molecular orbital (HOMO) level of a red host of the red light-emitting material layer is higher than a highest occupied molecular orbital (HOMO) level of a green host of the green light-emitting material layer, and
wherein the highest occupied molecular orbital (HOMO) level of the green host of the green light-emitting material layer is higher than a highest occupied molecular orbital (HOMO) level of a blue host of the blue light-emitting material layer.

17. The method of claim 12, wherein a lowest unoccupied molecular orbital (LUMO) level of a red host of the red light-emitting material layer is lower than a lowest unoccupied molecular orbital (LUMO) level of a green host of the green light-emitting material layer, and
wherein the lowest unoccupied molecular orbital (LUMO) level of the green host of the green light-emitting material layer is lower than a lowest unoccupied molecular orbital (LUMO) level of a blue host of the blue light-emitting material layer.
